(19) United States
(12) Patent Application Publication
(10) Pub. No.: US 2007/0131927 A1
(43) Pub. Date: Jun. 14, 2007

(54) THIN FILM TRANSISTOR AND MANUFACTURING METHOD THEREOF

(75) Inventors: Haruo KAWAKAMI, Hino City (JP); Hisato KATO, Hino City (JP); Takahiko MAEDA, Hino City, Tokyo (JP); Nobuyuki SEKINE, Hino City (JP)

Correspondence Address: ROSSI, KIMMS & McDOWELL LLP., P.O. BOX 826, ASHBURN, VA, 20146-0826, US

(73) Assignee: FUJI ELECTRIC HOLDINGS CO., LTD., Kawasaki-ku (JP)

(21) Appl. No.: 11/537,959

(22) Filed: Oct. 2, 2006

(30) Foreign Application Priority Data
Oct. 31, 2005 (JP) JP 2005-317486

(51) Int. Cl. H01L 29/08

(52) U.S. Cl. 257/40

(57) ABSTRACT

An OTFT is formed by forming a pair of recesses, one being a groove and another being groove or a hole. A source electrode is formed by filling one of the recesses. A drain electrode is formed by filling the other one of the recesses. A film of organic semiconductor material is formed on the source electrode and the drain electrode and makes electrical contact therewith. A gate insulating film is formed on the film of organic material, and a gate electrode is formed on the gate insulating film. The method of manufacturing the OTFT allows realization of high precision microfabrication of the source electrode and the drain electrode formed on the substrate such as a plastic substrate by an inexpensive process.

### BACKGROUND

Flat displays are becoming widely available. Liquid crystal displays represent one kind of flat displays, in which light from a backlight is controlled on-off by an optical shutter function of a liquid crystal, and colored light is obtained by means of a color filter. In comparison, in an Organic Electroluminescent (OEL) or Organic Light-Emitting Diode (OLED) display, as another kind of flat displays, light is presented by individual light emission of each pixel (i.e., by spontaneous light emission of each pixel). Therefore, an organic EL display not only can provide a wide viewing angle, but also requires no backlight. This provides a number of advantages, such as enabling a thinner display and a flexible display (display formable on a flexible substrate). Thus, an OEL or OLED display is expected to be the next-generation displays.

The driving systems of the panel for such a display can be roughly classified into two types. A first type of driving system is referred to as a passive matrix type (also called duty driving system or simple matrix system). In this system, a plurality of stripe-shaped electrodes are arranged in rows and in columns in a matrix-like configuration. At each intersection of a row electrode and a column electrode, a pixel is formed to emit light by driving signals applied to the row electrode and the column electrode, respectively. Normally, the row electrodes are scanned, i.e., the row electrodes are individually selected by a signal in time sequence for light-emission control of the pixels in the respective row. While a certain row electrode is selected, to all of the column electrodes, their respective signals for light-emission control in the selected row are simultaneously applied. The system is normally provided with no active element for each of the pixels so as to carry out light-emission control only in the duty period of each row within the scanning period of all rows.

A second kind of driving system is referred to as an active matrix type in which each of a plurality of pixels has a switching element associated therewith that allows the pixel to emit light throughout the scanning period of all rows. For example, suppose a case in which the panel with pixels of 100 rows and 150 columns is made to emit light with a displaying luminance of 100 Cd/m². In this case, in a panel of the active matrix type, each of the pixels basically always emit light. Hence, a pixel can be made to emit light with a luminance of 100 Cd/m² when the area factor and various kinds of losses of the pixel are not taken into consideration. In a panel of the passive matrix type with the same pixel arrangement, however, the duty ratio of a signal driving each of the pixels becomes 1/100 and only the duty period (selection period) is given as the time of light-emission. Therefore, for obtaining the same displaying luminance as that in the panel of the active matrix type, a luminance of light-emission in the light-emitting period of a pixel must be increased by a factor of 100, namely to 10000 Cd/m².

To increase the luminance of light-emission, the current flowing in the light-emitting element can be increased. However, in an OEL element, it is known that the light-emission efficiency becomes lower as the current is increased. The lowered efficiency causes the passive matrix type to consume more power than the active matrix type when the displaying luminance levels are the same in both cases. Moreover, increasing the current flow in an OEL element can deteriorate its material due to the greater heat generation, thus shortening the lifespan of the display. The maximum current value is limited from the viewpoint of enhancing the efficiency and the lifetime results in the requirement for a lengthened light-emitting period for obtaining the same displaying luminance. The lengthened light-emitting period, however, limits the displaying capacity (the number of driving lines) because the duty ratio determining the time of light-emission in the passive matrix type driving system is the reciprocal of the number of rows in the display panel. A display panel with a large area and a high resolution or pixel density, such as a high-definition television, necessitates the use of an active matrix type driving system.

A basic example of a light-emitting element control circuit for an ordinary active matrix type driving system is known as a circuit using thin film transistors (TFTs) as switching elements as shown in FIG. 2. In the circuit shown in FIG. 2, the source of a driving TFT 130 is connected to a light-emitting element (OEL element) 110 connected to a second column electrode 117. The driving TFT 130 has its drain connected to a second row electrode 104 and its gate connected to the source of a switching transistor 131. The source of the switching transistor 131 is also connected to the second row electrode wire 104 through a capacitor 106. Furthermore, the drain and the gate of the switching transistor 131 are connected to a first column electrode 116 and a first row electrode 103, respectively.

In an active matrix type driving system suited for a display panel with a large area and a high resolution, a TFT using polysilicon is most widely used as a switching element of a pixel. However, the process for forming a TFT using polysilicon requires a high temperature, namely 250° C. or higher. Thus, it is difficult to use a flexible plastic substrate that does not have sufficient heat resistance, limiting the selection thereof.

To counter such various kinds of problems presented in known display panels, an organic thin film transistor (OTFT) has long been proposed. For example, JP-A-2001-250680 discloses an organic thin film rectifying element that is connected in series to an organic thin film light-emitting section. In addition, WO 01/15233 discloses a drive control of a pixel that is carried out by an OTFT, which enables the manufacturing process thereof to be carried out at a lower temperature to thereby allow the use of a flexible plastic substrate. Moreover, in manufacturing the driving element, a low cost material and a low cost process can be selected to reduce the cost of a display panel.

Such OTFTs, however, present the following problems. Typical structures of OTFTs may be roughly classified as a bottom contact structure as shown in FIG. 3, a top contact structure as shown in FIG. 4, and a top gate structure as shown in FIG. 10. In the bottom contact structure, a source electrode 15 and a drain electrode 14 are formed on a gate insulating film 12 directly or with a bonding layer placed therebetween. Thereafter, a film of organic semiconductor material 13 is formed thereon to provide the structure. In the top contact structure, the film of organic semiconductor material 13 is formed on the surface of the substrate 10, the gate insulating film 12 is formed on the gate insulating film 12 before the source electrode 15 and the drain electrode 14 are formed thereon. In each of the two structures, a gate electrode 11 is formed on the side of the substrate 10 (bottom gate). In the top gate structure, the film of organic semiconductor material 13 is formed on the surface of the substrate 10, the gate insulating film 12 is formed on the film 13, and the gate electrode 11 is formed on the surface of the gate insulating film 12. The top gate structure is particularly often used when the film of organic semiconductor material 13 is made of polymer material of an amorphous structure with a smooth surface.

In each of these structures, by applying a gate voltage to the gate electrode 11, electric charge carriers are induced in the film of organic semiconductor material 13 at a section in contact with the gate insulating film 12. The induced carriers are made to move by applying a voltage between the source electrode 15 and the drain electrode 14, by which current is induced. The current path between the source electrode 15 and the drain electrode 14 is referred to as a channel 16, which is usually formed at a very thin section with several molecular layers of the film of organic semiconductor material 13 in contact with the gate insulating film 12.

Examples of organic semiconductor material for an OTFT include pentacene, thiophen polymer, fluorene-thiophene polymer, copper phthalocyanine, and fullerane. Of these materials, in particular, low polymer materials such as pentacene, copper phthalocyanine, and fullerane are not soluble in a solvent at room temperature, so that they are generally formed by vacuum evaporation. In contrast, thiophene polymer and fluorene-thiophene polymer are soluble in a solvent, so that they can be formed into a thin film by a coating process. As no vacuum process is necessary in the latter case, the manufacturing cost can be reduced.

However, the mobility of carriers in the organic semiconductor materials is limited to 8 cm²/Vs or less even in pentacene, which has the highest mobility. This is smaller compared with 10 to 100 cm²/Vs of polysilicon used in TFTs for driving an OEL displays at present. In particular, the mobility in polymer material that can be formed as a thin film by a coating process even smaller and a value of 0.1 cm²/Vs or less has been reported. For example, the saturation current Isd of a field-effect transistor is generally expressed by the following expression:
Isd=(W/2L)*C*μ*(Vg−Vth)². (1),
where W and L are the channel width and the channel length of the transistor, respectively, C is capacitance per unit area of the gate insulating film, μ is the carrier mobility in the organic semiconductor material, Vg is the gate voltage, and Vth is the threshold value of the gate voltage. For obtaining a sufficiently large Isd under a certain voltage condition, it is desirable to have a large C and μ values. However, C and μ are physical property values inevitably determined by the material being used. The channel width W is limited by the area for forming the element. On the other hand, the channel length L can be minimized theoretically down to 10 nm by means of, for example, photolithography. Thus, by minimizing the channel length L, a large saturation current Isd can be obtained even with a material with small carrier mobility.

However, for obtaining a small channel length L, an expensive process is necessary. For example, an ordinary photo process, though it has a high working accuracy, generally costs high. Particularly for obtaining a high working accuracy of several micrometers or less, a highly expensive facility is necessary. Moreover, with the electrically conductive material that can be particularly formed into a thin film by coating, electrodes were sometimes formed by various kinds of printing (IJP, padding, flexographic printing, and gravure printing, for example). However, the limit of dimensional accuracy obtained with those techniques was approximately 20 μm, which made it difficult to accurately obtain a channel length of 10 μm or less, which was necessary for achieving the above purpose.

In addition, when an inexpensive plastic substrate in particular is used as a substrate, the large thermal expansion coefficient of the substrate makes it difficult to match positions of patterns formed in patterning process steps different from one another. The dimensional accuracy of the channel width W, as well as that of the channel length L, directly affects characteristics of the transistor. Therefore, it is desirable for at least the source electrode 15 and the drain electrode 14 to be accurately formed and have a high degree of reproducibility.

Therefore, for taking advantage of an organic material, there remains a need for forming an OTFT at a low cost with high dimensional accuracy. In particular, there remains a need for a way to make an OTFT inexpensively while allowing a high precision microfabrication of a source electrode and a drain electrode formed on a substrate, such as a plastic substrate. The present invention addresses these needs.

### SUMMARY OF THE INVENTION

The present invention relates to a TFT element using organic semiconductor material and a manufacturing method thereof.

One aspect of the present invention is a TFT. The TFT can include a substrate, a source electrode, a drain electrode, a gate electrode, a film of organic semiconductor material, and a gate insulating film.

The substrate, which can be made of thermoplastic material, can have a pair of recesses, one recess being a groove and the other recess being another groove or a hole. The source electrode can occupy one of the recesses and the drain electrode can occupy the other of the recesses. The film of organic material can be formed on the source electrode and the drain electrode and can make electrical contact therewith. The gate insulating film can be formed on the film of organic material, and the gate electrode can be formed on the gate insulating film.

At least one of the source electrode or the drain electrode can extend through the substrate. One of the source electrode or the drain electrode can be formed along an outer periphery of the other of the source or drain electrode with a spacing therebetween. One of the source electrode or the drain electrode can surround the other of the source or drain electrode with a spacing therebetween. Alternatively, each of the source and drain electrodes can have a comb-shaped structure, with the comb teeth portions thereof interlaced or disposed between adjacent teeth so that at least one of the comb teeth of the one electrode is disposed in the spacing between an adjacent pair of comb teeth of the other electrode.

Another aspect of the present invention is a method of manufacturing the TFT. The method can include providing the substrate, forming the pair of recesses in the substrate, one recess being the groove and the other recess being another groove or the hole, forming the source electrode in one of the recesses, forming the drain electrode in the other of the recesses, and forming the film of organic semiconductor material, the gate insulating film, and the gate electrode in this order on the substrate with the source and drain electrodes.

The pair of recesses can be formed by thermal imprinting. The source and drain electrodes can be formed by filling the recesses with one of a solution of an electrically conductive material or a liquid dispersion of an electrically conductive material.

### BRIEF DESCRIPTION OF THE DRAWINGS

FIGS. 1A to 1D are cross-sectional views showing the structure and the manufacturing steps of a first embodiment of the TFT according to the present invention.

FIG. 2 illustrates an example of a basic circuit of a light-emitting element control circuit for an ordinary active matrix type driving system using TFTs.

FIG. 3 is a cross-sectional view showing an example of a bottom contact structure of a related OTFT.

FIG. 4 is a cross-sectional view showing an example of a top contact structure of a related OTFT.

FIG. 5 is a cross-sectional plan view taken along line V-V of FIG. 1D.

FIGS. 6A to 6D are cross-sectional views showing the structure and the manufacturing steps of a second embodiment of the TFT according to the present invention.

FIG. 7 is a cross-sectional plan view taken along line VII-VII of FIG. 6D.

FIG. 8 is a cross-sectional plan view showing the structure of a third embodiment of the TFT according to the present invention.

FIG. 9 is a cross-sectional plan view showing the structure of a fourth embodiment of the TFT according to the present invention.

FIG. 10 is a cross-sectional view showing an example of a top gate structure of a related OTFT.

FIG. 11 is a cross-sectional view showing the structure of the TFT of Comparison Example 2, which is compared with Example 4.

FIG. 12 is a cross-sectional view showing the structure of the TFT of example 5.

### DETAILED DESCRIPTION

A transistor is a thin film field-effect transistor in which a film of organic semiconductor material, a gate insulating film, and a gate electrode are laminated. The path of current flowing between its source electrode and its drain electrode, which are formed separate from the lamination, is provided through the film of organic semiconductor material in contact with the gate insulating film. The current is controlled by the electric potential of the gate electrode. Each of the source electrode and the drain electrode is buried in a recess, which can be a groove or a hole formed in a substrate, with the film of organic material for the electronics, the gate insulating film, and the gate electrode formed or laminated thereon to form the transistor.

The grooves or the holes can be formed by thermal imprinting. In the case of using thermoplastic material as the material for the substrate, the substrate formed with desired grooves also can be fabricated by another method, such as extrusion for example. The size of the substrate is limited by the dimension of a mold in the extrusion process. In contrast, thermal imprinting is a method in which an debossing die necessary for forming the grooves or the holes is pressed against the substrate heated up to a glass transition point or above. Therefore, there is basically no limitation in the size of the substrate, so that the method is suited for successively forming grooves on large size substrates.

For the material of a substrate, photo-setting resin also can be used. In that case, after grooves or holes are formed on the resin by debossment, the resin is irradiated with light for setting, by which the grooves or the holes are provided. In this case, the resin generally lacks elasticity after being set. Therefore, when flexibility is required for the resin as a product, delicate care of the setting condition must be taken.

The heating temperature of the substrate when the grooves or the holes are formed is ordinarily 100° C. to 300° C., although the temperature depends on the substrate material being used. The pressure applied to the substrate for forming the grooves or the holes typically can be 10 to 200 MPa. The material of the debossing die used for forming the grooves or the holes is not particularly limited. It can be silicon, silicon carbide, sapphire, diamond, tantalum, SiO₂/Si, and SiN/Si, for example. The debossing die is preferably heated prior to working with the heating temperature, preferably to 100° C. to 350° C. The width of one of the grooves or the holes typically can be 10 nm to 50 μm although the width depends on the thickness of the debossing die. With a manufacturing method of the TFT according to the invention, a TFT can be obtained with a substrate area of 100 nm² or more, more preferably 1 μm² or more.

The spacing between the grooves or the holes is equivalent to a channel length. The channel length can be 1 to 50 μm. The preferable upper limit of the channel length is preferably 30 μm, and more preferably, 12 μm.

The source electrode or the drain electrode can be formed by pouring a solution of electrically conductive material or liquid dispersion of electrically conductive material in each of the grooves or the holes formed in the substrate. The solution or the liquid dispersion enters the grooves or the holes by the capillarity action or surface tension even when each of the grooves or the holes has a high aspect ratio. Thus, compared with other film forming measures, the electrodes can be easily formed. Moreover, it becomes possible to form the source electrode or the drain electrode inexpensively, with high accuracy and high reproducibility without using such measures as highly expensive photolithography.

Moreover, the TFT can be formed with at least one of the source electrode and the gate electrode penetrating the substrate to provide electrical connection on the substrate surface opposite to the substrate surface on which the film of organic semiconductor material, the gate insulating film, and the gate electrode are presented. With such an arrangement, the wiring of the source electrode and the wiring of the drain electrode are separately provided on the respective opposite surfaces of the substrate. This provides advantage of facilitating matrix-like wiring necessary for display driving. Namely, even with an arrangement in which a lead wire on the side of the source electrode of the TFT and the lead wire on the side of the drain electrode orthogonally intersect with each other, the wires are separately formed on the respective opposite surfaces of the substrate. Thus, there is no need to form an insulating film at the intersection of the wires. A particularly preferable embodiment is shown as a structure with one of the electrodes penetrating the substrate so that it is completely surrounded by the other electrode.

For the electrode made to penetrate the substrate, for ensuring electrical connection thereto, a supplementary electrode can be provided on the substrate surface opposite to the substrate surface on which the film of organic semiconductor material, the gate insulating film, and the gate electrode are presented.

One of the source electrode or the drain electrode can be formed along the outer periphery of the other electrode in the substrate surface. Here, “to be formed along the outer periphery” means that at least a part of the contour of one of the electrodes is formed so as to surround a part of the contour of the other one of the electrodes with certain spacing. Therefore, when it is said that one of the electrodes is formed along the outer periphery of the other electrode in the substrate surface, the case is not limited to one in which one of the electrodes is enclosed by the other electrode, but can include for example one in which two comb-shaped electrodes are formed opposite to each other so that the comb teeth of the one electrode are disposed in the spaces between the comb teeth of the other electrode.

The TFT can be provided as one in which one of the source electrode and the drain electrode is surrounded by the other electrode. For example, by forming the drain electrode in column-like and forming the source electrode in a doughnut- or annular-shape around the drain electrode, the source electrode can be made to function as a so-called guard ring to thereby suppress current leaks. However, for forming the doughnut-shaped electrode as a closed loop surrounding the other electrode inside by means of photolithography, two or more exposure processes may be needed, which are further accompanied with highly difficult processes such as pattern positioning. In contrast, the thermal imprinting is particularly suitable here in that the pattern of the two electrodes can be formed by one time operation without losing the relative position between the two electrodes.

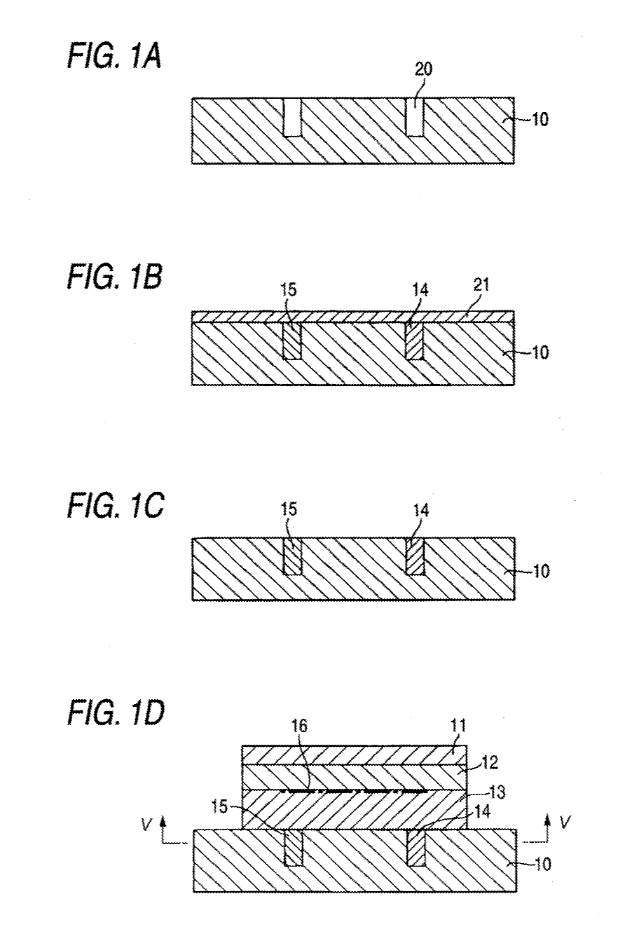

A first embodiment of the TFT according to the invention is shown in FIGS. 1A to 1D. A heated debossing die is pressed against a thermoplastic substrate 10 to form two grooves 20 (FIG. 1A). Thereafter, a solution of an electrically conductive material or a liquid dispersion of an electrically conductive material is applied to the substrate 10. The solution or the liquid dispersion is poured into the substrate and fills the grooves 20 by surface tension or capillary action (FIG. 1B). For facilitating the filling, it is possible to make the inside of the grooves 20 hydrophilic before the filling by an ozone exposure process or a coating with various hydrophilic processing materials. After the solution or the liquid dispersion has dried and set up, the extraneous electrically conductive material 21 outside the grooves is removed by oxygen plasma, by which a structure is formed in which a source electrode 15 and a drain electrode 14 are formed with a certain spacing from each other (FIG. 1C).

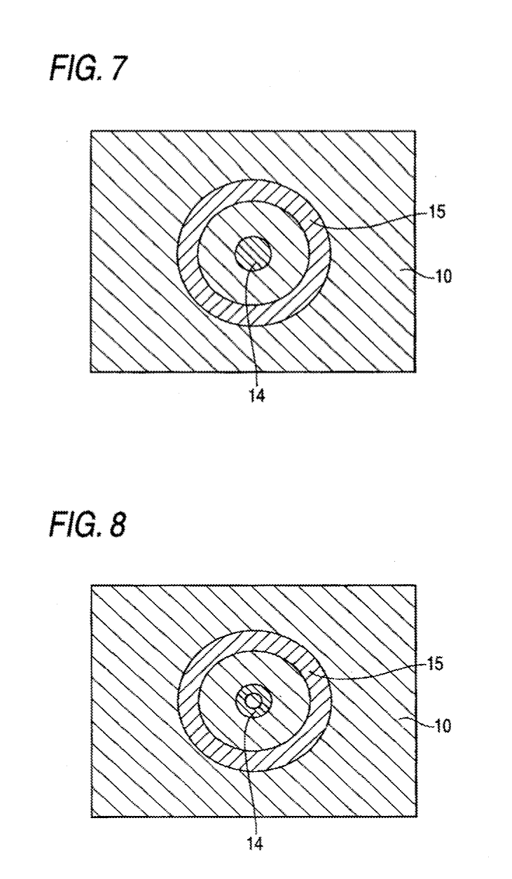

In some cases, drying of the applied solution or the liquid dispersion causes shrinkage in volume thereof to produce a gap in the recess, the groove or the hole (see FIGS. 7 and 8). However, as long as an electrical connection is provided, no functional problem arises from such a gap. When the gap must be filled in for other reasons, a solution with a relatively high concentration or multiple coats of the solution can be applied.

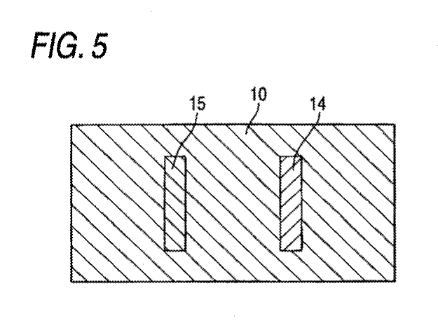

On the substrate 10 with the source electrode 15 and the drain electrode 14 formed thereon, a film of organic semiconductor material 13, a gate insulating film 12, and a gate electrode 11 are formed in this order such as by a vacuum evaporation or spin coating or printing technique (FIG. 1D). A channel 16 for carriers is formed in a region between the source electrode 15 and the drain electrode 14 in the film of organic semiconductor material 13 in the vicinity of the interface with the gate insulating film 12. FIG. 5 illustrates a cross-sectional plan view of the structure taken along line V-V of FIG. 1D.

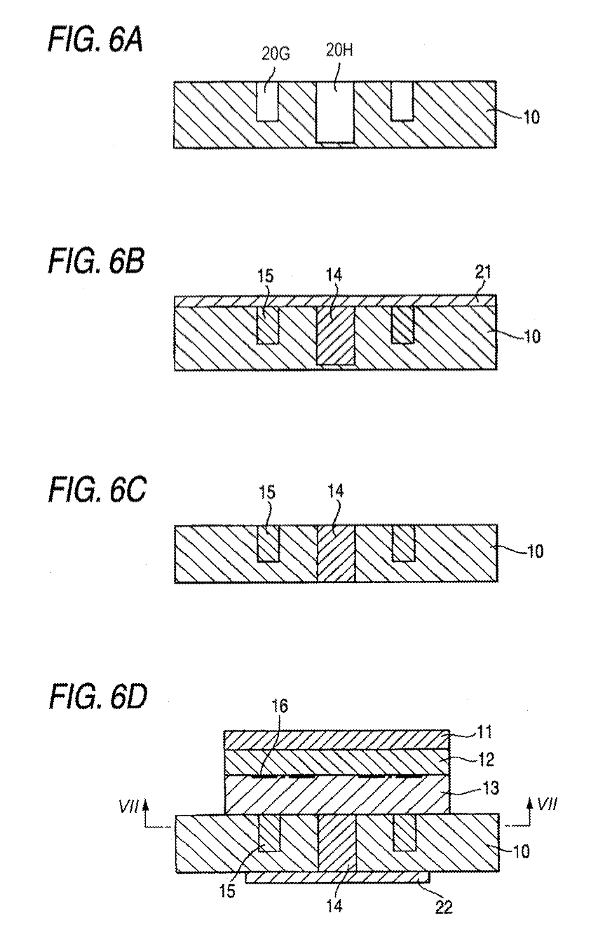

FIGS. 6A to 6D are cross-sectional views showing a second embodiment of the TFT. FIG. 7 is a cross-sectional plan view taken along line VII-VII of FIG. 6D. In the second embodiment, a cylindrical hole 20H and a ring-shaped groove or channel 20G surrounding the hole 20H are formed in the substrate 10 (FIG. 6A) by the same thermal imprinting method used in the first embodiment. The hole 20H is formed deeper than the groove 20G. Then, by the same method as that in the first embodiment, a solution of electrically conductive material or liquid dispersion of an electrically conductive material is poured into the hole 20H and the groove 20G to form a drain electrode 14 and a source electrode 15. The drain electrode 14 is formed to have a depth deeper than that of the source electrode 15 (FIG. 6B). Thereafter, almost simultaneously with the removal of extraneous electrically conductive material 21 on the substrate surface outside the groove and the hole, the substrate surface opposite to that with the electrodes is etched so that the drain electrode 14 penetrates the substrate 10 to the opposite surface (FIG. 6C). Thereafter, the film of organic semiconductor material 13, the gate insulating film 12, and the gate electrode 11 are formed in the same way as in the first embodiment. An electrode 22 for ensuring electrical connection to the drain electrode 14 can be formed on the opposite surface (FIG. 6D).

In the second embodiment, the source electrode 15 is formed along the outer periphery of the drain electrode 14 to also play a role of a guard ring. Therefore, an arrangement is provided by which leak current due to a drain voltage can be prevented. Such an arrangement including grooves of multiple closed curves cannot be provided by a single process in a method using a mask such as photolithography because there is no supporting structure for a mask determining inner contours of the grooves. In contrast, the method according to the present invention can easily provide such arrangement by a single process when the debossing die for the arrangement has been prepared.

As a third embodiment, an arrangement as shown in FIG. 8 also can be easily provided in which the drain electrode 14 positioned inside a ring-shaped source electrode 15 also is doughnut or ring-shaped. In this case, compared with the area of the hole for the drain electrode 14 shown in FIG. 7, the area of the groove for the drain electrode 14 becomes smaller to facilitate filling of a solution of an electrically conductive material by capillary action or surface tension. When the drain electrode 14 is made to penetrate the substrate 10, a structure is provided in which the substrate inside the drain electrode 14 is supported through the electrically conductive material of the drain electrode 14.

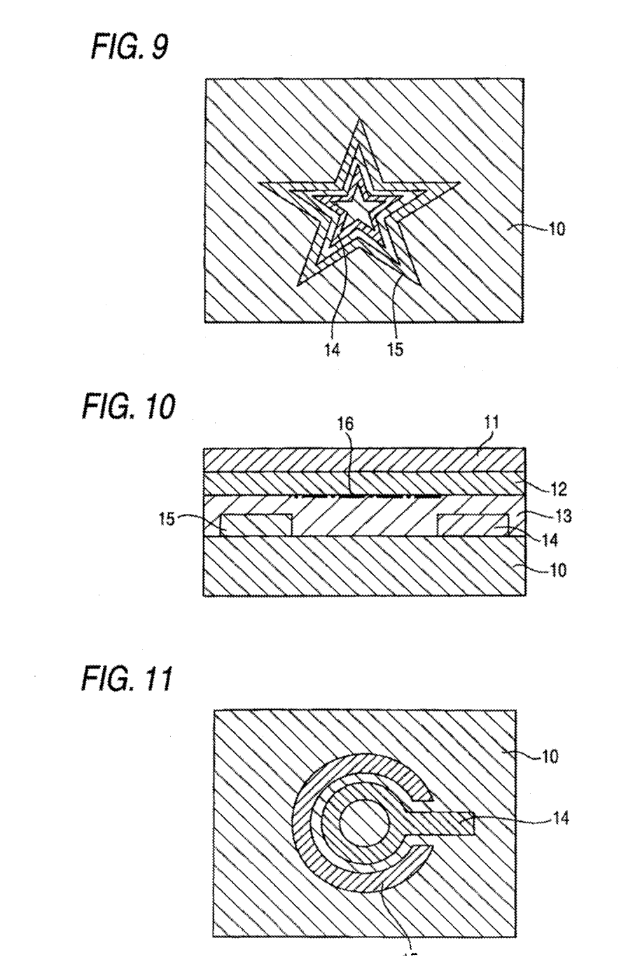

As a fourth embodiment, as shown in FIG. 9, an arrangement can be of course provided in which each of the plane shapes of the drain electrode 14 and the source electrode 15 is made to have a configuration other than generally circular. Here, the electrodes are star shaped to increase the outer peripheral length thereof. This increases the channel length to increase the saturation current Isd of the transistor.

In the above embodiments of FIGS. 5-9, the source electrode and the drain electrode can be reversed.

Comparisons made between the thus formed structures of the TFTs according to the invention and the known element structures, i.e., the bottom contact structure in FIG. 3, the top contact structure in FIG. 4, and the top gate structure in FIG. 10, reveal that the manufacturing method according to the present invention has the following advantages. It requires less capital investment and facilitates the manufacturing process in contrast with each of the methods for the bottom contact structure and the top gate structure requiring an expensive facility and a number of processings because the source electrode and the drain electrode are formed by photolithography or similar methods. The cost advantage becomes particularly remarkable when a fabrication that makes the channel length 10 μm or less is carried out. Since the source electrode and the drain electrode in the top contact structure are formed by originally using a shadow mask, it was difficult to form a channel length of 30 μm or less with the known methods.

Thus, the method according to the present invention avoids the problems associated with known methods and makes it possible to realize a high precision microfabrication by an inexpensive process.

For the organic semiconductor materials, in addition to acene series compounds, such as pentacene, tetracene and anthracene, for example, materials such as lubrene, thiophene, hexyl thiophene series polymer, fluorene/thiophene series polymer, copper phthalocyanine and fullerane are preferable. These materials represent examples only and many other organic semiconductor materials can be used. The particular organic semiconductor material is not critical to the present invention.

With respect to the source electrode and the drain electrode, various kinds of metallic materials and organic electrically conductive materials are applicable. When the major carriers in the organic semiconductor material are holes, for example, a material with a large work function is suitable as electrode material to enhance the injection of the holes at the source electrode and inhibit the injection of electrons at the drain electrode. In particular, as a metallic material, a material including fine particles of noble metal such as Au, Ag, or Pt as the main ingredient, which is easily prepared as a liquid dispersion, is suitable. Moreover, as organic electrically conductive materials, poly-3, 4-ethylene dioxythiophene/polystylene-sulfonate (PEDOT/PSS) and polyaniline (PAN I) are suitable.

As the material of the gate insulating film, various kinds of metallic oxides, oxides of metals such as silicon, aluminum, tantalum, titanium, strontium, and barium, for example, and mixed oxides of the metallic oxides can be used. Moreover, macromolecular materials, for example, polymer materials such as polystyrene, polyvinyl alcohol, polyvinyl phenol and acrylic resin also can be used. Moreover, the macromolecular materials also can be used with metallic oxides dispersed therein. In particular, many of metallic oxides have higher permittivities compared with those of macromolecular materials. Thus, a gate insulating film using such a metallic oxide is characterized by enabling a transistor to be driven by a relatively low voltage. While, macromolecular material has a relatively low permittivity. Thus, a gate insulating film using macromolecular material is characterized by enhancing a high speed response of a transistor.

With respect to the gate electrode, various kinds of metallic materials and organic electrically conductive materials are applicable. The material is determined by considering such items as adhesive properties to the gate insulating film and easiness in formation.

For the substrates on which the elements are formed, various kinds of materials can be used. When the grooves or the holes are formed by thermal imprinting, a thermoplastic material is preferable. As to thermoplastic materials, there is no limitation and polymer films of materials such as, for example, polyether imide (PEI), polyether etherketone (PEEK), polyethylene terephthalate (PET), polyethylene naphthalate (PEN), polyether sulfon (PES), polyphenylene sulfide (PPS), polycarbonate (PC), polystyrene (PS), and polymethyl methacrylate (PMMA) can be used.

The aspect ratio of the grooves and holes of the TFT is preferably 1 to 40. The more preferable upper limit of the aspect ratio is 30 and the more preferable lower limit is 3.

The following Examples provide some exemplary examples according to the present invention. The present invention, however, is not to be limited to the examples expressly provided herein. In Example 1, a polyethylene naphthalate (PEN) substrate 10 (100 μm in thickness) was heated to 220° C., into which a separately formed debossing die of silicon was pressed while being heated to 270° C. to thereby form two grooves, each having a width of 20 μm, a length of 100 μm (corresponding to the channel width) and a depth of 60 μm, at a distance of 10 μm (corresponding to the channel length) from each other. The grooves were irradiated with ultraviolet light with a wavelength of 254 nm to make the surfaces of the grooves hydrophilic. Thereafter, a PEDOT/PSS solution (“A14083” produced by Bayer Ltd.) as a solution of electrically conductive material was applied to the surface of the substrate 10 by spin coating. The rotating speed and the rotating time in the spin coating were 1000 rpm and 180 seconds, respectively. After the entrance of the applied PEDOT/PSS solution into the grooves by capillarity action was confirmed, the applied solution was dried at 120° C. for 10 minutes.

Next, the PEDOT/PSS material falling outside the grooves was etched by oxygen plasma, by which electrical insulation between the two grooves was secured. At this time, conducting sections for obtaining electrical connection with an external circuit were retained by providing masks thereon to prevent them from being etched.

Thereafter, a thiophene series polymer and poly (3-hexyl thiophene) (P3HT) (produced by Merck Ltd.) were dissolved in p-xylene in concentration of 2 mg/ml. By applying the thus prepared solution to the substrate 10 by spin coating, a film of organic semiconductor material 13 was obtained with a thickness of 30 nm. Thereafter, polystyrene (produced by Aldoritch Ltd.) was dissolved in ethyl acetate in concentration of 70 mg/ml. By applying the thus prepared solution to the film of organic semiconductor material 13 by spin coating, the gate insulating film 12 was obtained with a thickness of 300 nm. Finally, by depositing aluminum on the polystyrene gate insulating film 12 by vacuum evaporation, the gate electrode 11 with a thickness of 60 nm was obtained. The resulting process formed a test sample of Example 1.

In Example 2, a substrate of a polyethylene naphthalate (PEN) sheet with a thickness of 100 μm, having two grooves formed therein at a distance of 5 μm (corresponding to the channel length) from each other, was prepared by extrusion. Each groove was formed to have a width of 20 μm, a length of 100 μm (corresponding to the channel width) and a depth of 60 μm. Except for the use of thus prepared substrate, the same procedures as those in Example 1 were carried out, to form a test sample of Example 2.

In Example 3, instead of the PEDOT/PSS solution, a liquid dispersion of Ag fine particles (“Nanometal Ink” produced by Shinku Yakin Co., Ltd.) was used for the electrically conductive material, which was then dried 150° C. for 120 minutes. Except for this difference and for etching of conducting sections other than the grooves and conducting sections for obtaining electrical connection with an external circuit having been carried out by using a dilute nitric acid, the same procedures as those in Example 1 were carried out to form a test sample of Example 3.

In Example 4, a polyethylene naphthalate (PEN) substrate 10 (50 μm in thickness) was heated to 200° C., into which a separately formed debossing die of silicon was pressed into the substrate while being heated to 260° C., by which an inner circular groove with an inner diameter of 30 μm, an outer diameter of 40 μm and a depth of 30 μm and an outer circular groove with an inner diameter of 50 μm, an outer diameter of 60 μm and a depth of 45 μm were formed concentrically. The distance of 10 μm between the two circular grooves corresponds to the channel length and each of the circumferential lengths of the circles of the grooves (40 μm and 50 μm in terms of diameters) facing the channel corresponds to the channel width. In the same way as in Example 1, the grooves were irradiated with ultraviolet light with a wavelength of 254 nm to make the surfaces thereof hydrophilic. Thereafter, a PEDOT/PSS solution (“A14083” produced by Bayer Ltd.) as a solution of electrically conductive material was applied to the surface of the substrate 10 by spin coating. Thereafter, the opposite surface of the substrate was polished by oxygen plasma etching to make the outer groove, filled with the drain electrode 14, penetrate the substrate. Thereafter, in the same way as in Example 1, a thiophene series polymer and poly (3-hexyl thiophene) (P3HT) (produced by Merck Ltd.) were dissolved in p-xylene in concentration of 2 mg/ml. By applying the thus prepared solution to the substrate 10 by spin coating, the film of organic semiconductor material 13 with a thickness of 30 nm was obtained. Thereafter, polystyrene (produced by Aldoritch Ltd.) was dissolved in ethyl acetate in concentration of 70 mg/ml. By applying the thus prepared solution to the film of organic semiconductor material 13 by spin coating, the gate insulating film 12 with a thickness of 300 nm was obtained. Finally, by depositing aluminum on the polystyrene gate insulating film 12 by vacuum evaporation, the gate electrode 11 with a thickness of 60 nm was formed. The resulting product formed a test sample of Example 4.

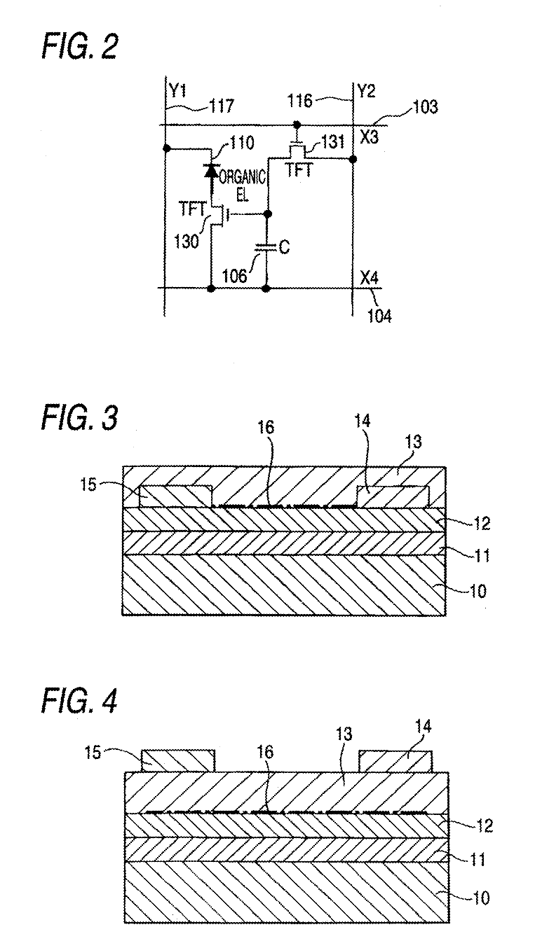

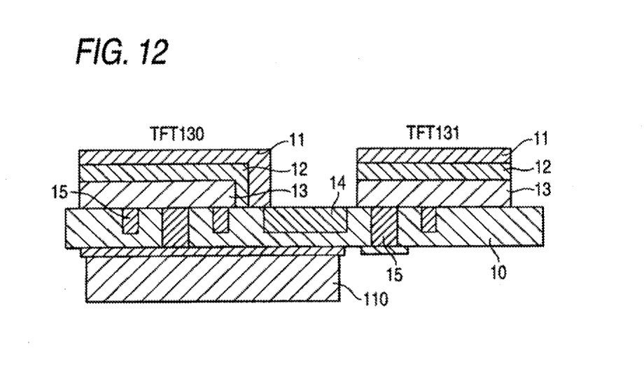

By the same method as in Example 4, in Example 5, 100 combinations each including two TFTs were formed in a matrix of 10 rows by 10 columns. To the two TFTs, a driving TFT 130 and a switching TFT 131, in each combination, a capacitor 106 and a light-emitting element (an OEL element) 110 were added, respectively, to form a light-emitting element control circuit as shown in FIG. 2. Moreover, as shown in FIG. 12, in the structure of each combination, the gate electrode 11 of each of the driving TFT 130 and the switching TFT 131 was formed on the same side of the substrate 10. Furthermore, in the switching TFT 131, an electrode penetrating the substrate was used as the source electrode 15 and an outer electrode surrounding the source electrode 15 was used as the drain electrode 14. In this way, a first row electrode wire 103, a second row electrode wire 104 and a capacitor 106 shown in FIG. 2 were placed on the side of the gate electrodes 11 of the TFTs 130 and 131. Moreover, a light-emitting element 110, a first column electrode wire 116, and a second column electrode wire 117 were to be placed on the substrate surface on the opposite side of the gate electrodes 11 (in FIG. 12, illustration of constituents other than the TFTs 131 and 132 and the light-emitting element 110 are omitted).

As Comparison Example 1, an element having a structure similar to that of the element in Example 1 was formed in a known top gate structure by using photolithography. Namely, a photoresist (“OFPR-800” produced by Tokyo Ohka Kogyo Co., Ltd.) was applied to a substrate with a thickness of 2 μm by spin coating. Thereafter, the applied photoresist was irradiated through a photomask with ultraviolet light with a wavelength of 405 nm and a power density of 11 mW/cm² for 4 seconds to set the irradiated section. At the respective sections at which a source electrode and a drain electrode were to be formed, two images of shadows, at which no ultraviolet light was projected and each of which had a width of 20 μm and a length of 100 μm, were formed at a distance of 10 μm (corresponding to the channel length) from each other. After this, with the use of a developing solution (“NMD-3” produced by Tokyo Ohka Kogyo Co., Ltd.), development was carried out with the sections not irradiated with ultraviolet light washed away. Then, pre-baking at 110° C. for 90 seconds and post-baking at 130° C. for 30 minutes were carried out. On the thus processed element, a gold thin film with a thickness of 100 nm was formed by vacuum evaporation. Furthermore, after the photoresist was stripped off by the lift-off method, the exposed substrate surface was irradiated with ultraviolet light with a wavelength of 254 nm to be cleaned. On the cleaned substrate surface, a poly (3-hexyl thiophene) (P3HT) (produced by Merck Ltd.) thin film as the film of organic semiconductor material 13, a polystyrene thin film as the gate insulating film 12 and an aluminum thin film as the gate electrode 11 were formed in the same way as in Example 1. Thus, a test sample of Comparison Example 1 was formed.

As Comparison Example 2, a test sample having an arrangement similar to that in Example 4 was fabricated with a known structure formed on a substrate surface. Namely, on a polyethylene terephthalate (PET) substrate 10 (50 μm in thickness), a doughnut-shaped inside electrode with an inner diameter of 30 μm and an outer diameter of 40 μm was formed as a drain electrode 14. Together with this, a doughnut-shaped outside electrode with an inner diameter of 50 μm and an outer diameter of 60 μm was formed as a source electrode 15. Both of the doughnut-shaped electrodes were formed by a method like that in comparison Example 1. Both of the electrodes were formed on the same plane. Thus, the necessity for providing the inside drain electrode 14 with electrical connection to the outside caused the outside source electrode 15 to have a C-shape with a cut-out as shown in FIG. 11.

The characteristics of the test sample elements of the foregoing Examples and the Comparison Examples are summarized in the Table. The elements in Example 1, Example 2, and Example 3 have substantially similar values of mobility and saturation currents Isd (Vg=−20V) compared with those of the elements in Comparison Example 1. The element in Example 2 has a value of W/L two times that of the elements in Example 1, Example 3, and Comparison Example 1, which makes the element in Example 2 have a value of saturation current Isd also becoming two times those of the elements in Example 1, Example 3, and Comparison Example 1. Leak currents of the elements of Examples 1, 2, and 3 are also substantially similar to that of Comparison Example 1. However, in the elements in each of Examples 1, 2, and 3, the standard deviation of Isd of fabricated 100 elements becomes slightly smaller with significantly reduced working hours (the time required for fabricating 100 elements). This is because the formation of the source electrode 15 and the drain electrode 14 requires a process of only three steps with each being facilitated for each of the elements in Examples 1 and 2 in comparison with a process of as many as eight steps for the element in Comparison Example 1. The three steps for each of the elements in Examples 1 and 2 are the steps of (1) forming grooves in a substrate, (2) applying electrically conductive material, and (3) etching. While, the eight steps for the elements in Comparison Example 1 are the steps of (1) applying a photoresist, (2) projecting ultraviolet light, (3) carrying out development, (4) carrying out pre-bake, (5) carrying out post-bake, (6) forming a gold thin film by vacuum evaporation, (7) carrying out photoresist liftoff, and (8) cleaning the substrate.

In Example 4, the working hours thereof are significantly shortened compared with those for the element of Comparison Example 2. In addition, the leak current is largely reduced compared with that of the element in Comparison Example 2. This is probably due to an imperfect guard ring effect by the source electrode 15 on the drain electrode 14 in the case of the element of Comparison Example 2.

In Example 5, an intersection of the row electrode and the column electrode on the substrate can be avoided to facilitate the fabrication process. In addition, there was a reduction in number of elements formed on the substrate surface on which the light-emitting elements were to be formed. This enabled an increase in the area ratio of the light-emitting element.

THE TABLE

| | | Averaged | Averaged | Standard | | |
|---|---|---|---|---|---|---|
| | | value of | value of | deviation | Leak | |
| | W/L | mobility | lsd | of lsd | current | Working hours |
| | (μm/μm) | (cm²/Vs) | (μA) | (%) | (nA) | (Relative value) |
| Example 1 | 100/10 | 0.021 | 0.34 | 2.5 | 0.32 | 10 |
| Example 2 | 100/5 | 0.018 | 0.59 | 1.3 | 0.54 | 7 |
| Example 3 | 100/10 | 0.023 | 0.36 | 2.7 | 0.47 | 11 |
| Example 4 | 125/10 | 0.017 | 0.34 | 3.0 | 0.02 | 18 |
| Comparison | 100/10 | 0.02 | 0.32 | 4.6 | 0.58 | 65 |
| Example 1 | | | | | | |
| Comparison | 120/10 | 0.019 | 0.37 | 4.1 | 0.10 | 72 |
| Example 2 | | | | | | |

The present method can be used to fabricate an OTFT with a high precision microfabrication of a source electrode and a drain electrode formed on a substrate, such as a plastic substrate, by an inexpensive process for stable realization of high performance. In addition, the present method can facilitate formation of a matrix-like wiring to the source electrode and the drain electrode and reduce leak current from the element of the transistor.

While the present invention has been particularly shown and described with reference to preferred embodiments thereof, it will be understood by those skilled in the art that the foregoing and other changes in form and details can be made therein without departing from the spirit and scope of the present invention. All modifications and equivalents attainable by one versed in the art from the present disclosure within the scope and spirit of the present invention are to be included as further embodiments of the present invention. The scope of the present invention accordingly is to be defined as set forth in the appended claims.

This application is based on, and claims priority to, JP PA 2005-317486, filed on 31 Oct. 2005. The disclosure of the priority application, in its entirety, including the drawings, claims, and the specification thereof, is incorporated herein by reference.

What is claimed is:

1. A thin film transistor comprising:
a substrate;
a source electrode;
a drain electrode;
a film of organic semiconductor material formed on the source electrode and the drain electrode and making electrical contact therewith;
a gate insulating film formed on the film of organic semiconductor material; and
a gate electrode formed on the gate insulating film,
wherein the substrate has a pair of recesses, one recess being a groove and the other recess being another groove or a hole, and
wherein the source electrode occupies one of the recesses and the drain electrode occupies the other of the recesses.

2. The thin film transistor as claimed in claim 1, wherein the substrate is made of a thermoplastic material.

3. The thin film transistor as claimed in claim 1, wherein at least one of the source electrode or the drain electrode extends through the substrate.

4. The thin film transistor as claimed in claim 2, wherein at least one of the source electrode or the drain electrode extends through the substrate.

5. The thin film transistor as claimed in claim 1, wherein one of the source electrode or the drain electrode is formed along an outer periphery of the other of the source or drain electrode with a spacing therebetween.

6. The thin film transistor as claimed in claim 2, wherein one of the source electrode or the drain electrode is formed along an outer periphery of the other of the source or drain electrode with a spacing therebetween.

7. The thin film transistor as claimed in claim 3, wherein one of the source electrode or the drain electrode is formed along an outer periphery of the other of the source or drain electrode with a spacing therebetween.

8. The thin film transistor as claimed in claim 4, wherein one of the source electrode or the drain electrode is formed along an outer periphery of the other of the source or drain electrode with a spacing therebetween.

9. The thin film transistor as claimed in claim 1, wherein one of the source electrode or the drain electrode surrounds the other of the source or drain electrode with a spacing therebetween.

10. The thin film transistor as claimed in claim 2, wherein one of the source electrode or the drain electrode surrounds the other of the source or drain electrode with a spacing therebetween.

11. The thin film transistor as claimed in claim 3, wherein one of the source electrode or the drain electrode surrounds the other of the source or drain electrode with a spacing therebetween.

12. The thin film transistor as claimed in claim 4, wherein one of the source electrode or the drain electrode surrounds the other of the source or drain electrode with a spacing therebetween.

13. The thin film transistor as claimed in claim 1, wherein each of the source and drain electrodes has a comb-shaped structure and is formed opposite to each other so that at least one of the comb teeth of the one electrode is disposed in a spacing between an adjacent pair of comb teeth of the other electrode.

14. The thin film transistor as claimed in claim 2, wherein each of the source and drain electrodes has a comb-shaped structure and is formed opposite to each other so that at least one of the comb teeth of the one electrode is disposed in a spacing between an adjacent pair of comb teeth of the other electrode.

15. The thin film transistor as claimed in claim 3, wherein each of the source and drain electrodes has a comb-shaped structure and is formed opposite to each other so that at least one of the comb teeth of the one electrode is disposed in a spacing between an adjacent pair of comb teeth of the other electrode.

16. The thin film transistor as claimed in claim 4, wherein each of the source and drain electrodes has a comb-shaped structure and is formed opposite to each other so that at least one of the comb teeth of the one electrode is disposed in a spacing between an adjacent pair of comb teeth of the other electrode.

17. A method of manufacturing a thin film transistor comprising the steps of:
providing a substrate;
forming a pair of recesses in the substrate, one recess being a groove and the other recess being another groove or a hole;
forming a source electrode in one of the recesses;
forming a drain electrode in the other of the recesses; and
forming a film of organic semiconductor material, a gate insulating film, and a gate electrode on the substrate with the source and drain electrodes.

18. The method of manufacturing a thin film transistor as claimed in claim 17, wherein the recesses are formed in the substrate by thermal imprinting.

19. The method of manufacturing a thin film transistor as claimed in claim 17, wherein the source and drain electrodes are formed by filling the recesses with one of a solution of an electrically conductive material or a liquid dispersion of an electrically conductive material.

20. The method of manufacturing a thin film transistor as claimed in claim 18, wherein the source and drain electrodes are formed by filling the recesses with one of a solution of an electrically conductive material or a liquid dispersion of an electrically conductive material.
